(19) United States
(12) Patent Application Publication
(10) Pub. No.: US 2020/0078897 A1
(43) Pub. Date: Mar. 12, 2020

(54) SYSTEMS AND METHODS FOR HEAT MANAGEMENT USING SPEED CONTROL FOR A POWER TOOL

(71) Applicant: MILWAUKEE ELECTRIC TOOL CORPORATION, Brookfield, WI (US)

(72) Inventor: Carter H. Ypma, Milwaukee, WI (US)

(21) Appl. No.: 16/562,473

(22) Filed: Sep. 6, 2019

Related U.S. Application Data
(60) Provisional application No. 62/727,865, filed on Sep. 6, 2018.

(51) Int. Cl. B23Q 15/12; G01R 19/00

(52) U.S. Cl. CPC B23Q 15/12; B23D 59/001; G01R 19/0092

(57) ABSTRACT

A power tool and method for heat management using speed control. The power tool includes a housing, a motor within the housing, and an electronic processor coupled to the motor. The electronic processor is configured to operate the motor at a first speed corresponding and determine whether the power tool has been unloaded for a predetermined amount of time during which the motor has been operated at the first speed. In response to determining that the motor has been unloaded for the predetermined amount of time, the electronic processor operates the motor at a second speed lower than the first speed. The electronic processor further determines whether the power tool is loaded while operating the motor at the second speed and operates the motor at the first speed in response to determining that the motor is loaded.

### RELATED APPLICATIONS

This application claims priority to U.S. Provisional Patent Application No. 62/727,865, filed on Sep. 6, 2018, the entire contents of which are incorporated herein by reference.

### FIELD OF THE INVENTION

This application relates to controlling speed of a power tool to prevent excessive heating of the power tool components.

### BRIEF DESCRIPTION OF THE SEVERAL VIEWS OF THE DRAWINGS

FIG. 1A is a perspective view of a power tool in accordance with some embodiments.

FIG. 1B is a perspective view of the power tool of FIG. 1A with a portion of the housing removed.

FIG. 2 is a block diagram of the power tool of FIG. 1A in accordance with some embodiments.

FIG. 3 is a flowchart of a method for heat management of the power tool of FIG. 1A in accordance with some embodiments.

### DETAILED DESCRIPTION OF THE INVENTION

Before any embodiments of the invention are explained in detail, it is to be understood that the invention is not limited in its application to the details of construction and the arrangement of components set forth in the following description or illustrated in the following drawings. The invention is capable of other embodiments and of being practiced or of being carried out in various ways.

One embodiment provides a power tool including a housing, a motor within the housing, a variable speed dial moveable between a plurality of positions to select an operating speed of the motor, and an electronic processor coupled to the motor and the variable speed dial. The electronic processor is configured to operate the motor at a first speed corresponding to a speed selected by the variable speed dial. The electronic processor is further configured to determine whether the power tool has been unloaded for a predetermined amount of time during which the motor has been operated at the first speed. In response to determining that the motor has been unloaded for the predetermined amount of time, the electronic processor operates the motor at a second speed lower than the first speed. The electronic processor further determines whether the power tool is loaded while operating the motor at the second speed. In response to determining that the motor is loaded, the electronic processor operates the motor at the first speed. In some embodiments, the predetermined amount of time is at least 1 minute. For example, the predetermined amount of time is between 1 minute and 5 minutes, 1 minute and 6 minutes, 1 minute and 10 minutes, 1 minute and 15 minutes, 2 minutes and 10 minutes, 3 minutes and 10 minutes, 5 minutes and 10 minutes, or 5 minutes and 15 minutes.

Another embodiment provides a method for heat management of a power tool including operating, using an electronic processor of the power tool, the motor at a first speed corresponding to a speed selected by a variable speed dial of the power tool. The method further includes determining, using the electronic processor, that the power tool has been unloaded for a predetermined amount of time during which the motor has been operated at the first speed. In response to determining that the motor has been unloaded for the predetermined amount of time, the electronic processor operates the motor at a second speed lower than the first speed. The method further includes determining, using the electronic processor, that the power tool is loaded while operating the motor at the second speed. In response to determining that the motor is loaded, the electronic processor operates the motor at the first speed. In some embodiments, the predetermined amount of time is at least 1 minute. For example, the predetermined amount of time is between 1 minute and 5 minutes, 1 minute and 6 minutes, 1 minute and 10 minutes, 1 minute and 15 minutes, 2 minutes and 10 minutes, 3 minutes and 10 minutes, 5 minutes and 10 minutes, or 5 minutes and 15 minutes.

Another embodiment provides a power tool including a housing, a motor within the housing, and an electronic processor coupled to the motor. The electronic processor is configured to operate the motor at a first speed. The electronic processor is further configured to determine whether the power tool has been unloaded for a predetermined amount of time during which the motor has been operated at the first speed. In response to determining that the motor has been unloaded for the predetermined amount of time, the electronic processor operates the motor at a second speed lower than the first speed. The electronic processor further determines whether the power tool is loaded while operating the motor at the second speed. In response to determining that the motor is loaded, the electronic processor operates the motor at the first speed. In some embodiments, the predetermined amount of time is at least 1 minute. For example, the predetermined amount of time is between 1 minute and 5 minutes, 1 minute and 6 minutes, 1 minute and 10 minutes, 1 minute and 15 minutes, 2 minutes and 10 minutes, 3 minutes and 10 minutes, 5 minutes and 10 minutes, or 5 minutes and 15 minutes.

In some embodiments of the power tool and the method, to determine that the power tool has been unloaded for a predetermined amount of time during which the motor has been operated at the first speed, the electronic processor continuously determines whether the power tool is unloaded and, when unloaded, whether the predetermined amount of time has elapsed using a timer. In some embodiments, of the power tool and the method, the electronic processor, while operating the motor at the first speed, determines that the power tool is loaded and resets the timer.

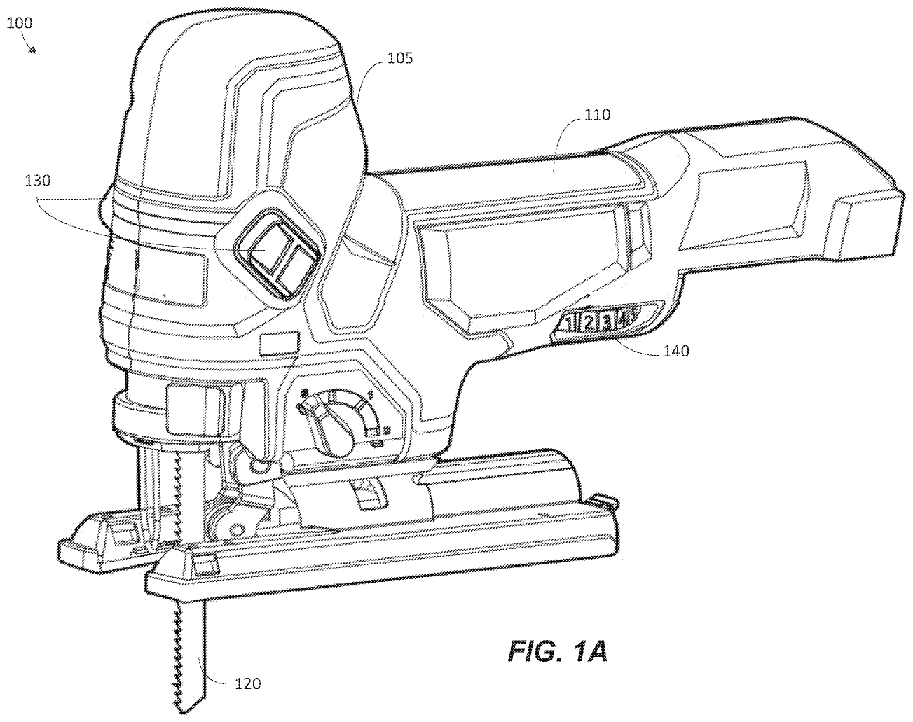

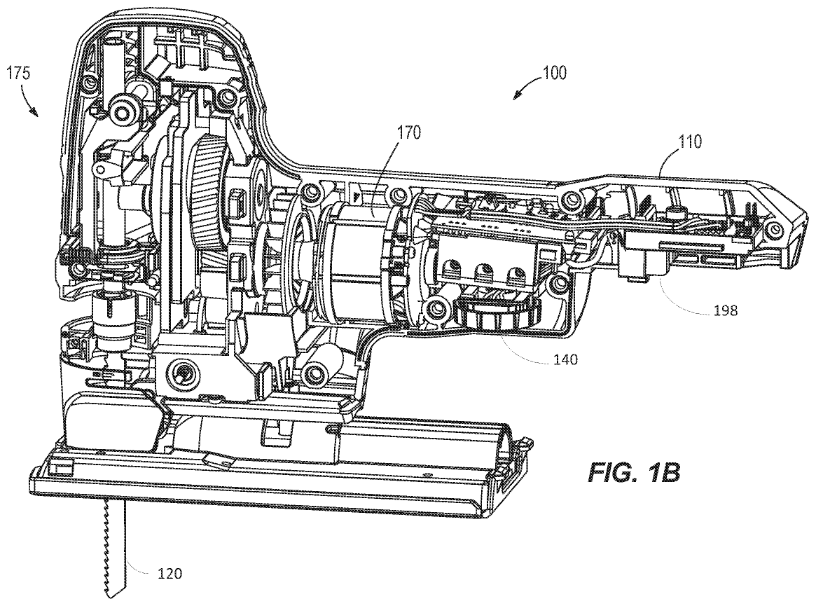

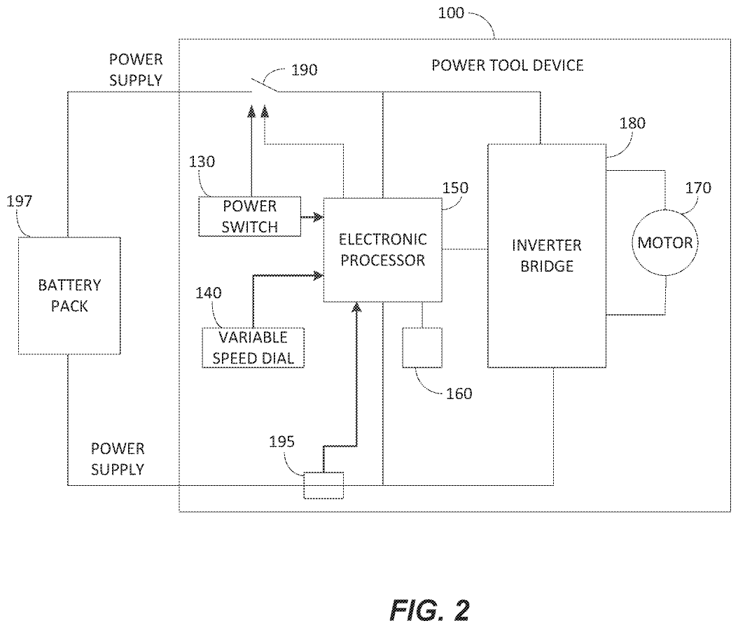

FIGS. 1A-B illustrates a power tool 100 including a housing 105, a handle 110, a blade 120, a power switch 130, and a variable speed dial 140. In the example illustrated, the power tool 100 is a jig saw. However, the embodiments described below may be applied to any power tool. With reference to FIG. 2, the power tool 100 includes an electronic processor 150, a memory 160, a motor 170, an inverter bridge 180, a discharge switch 190, and a current sensor 195. In the example illustrated, the power tool 100 is a cordless battery power jig saw that receives operating power from a connected battery pack 197. In other embodiments, the power tool 100 may be a corded AC jig saw that receives operating power from, for example, a wall outlet.

The electronic processor 150 may be implemented as, for example, a microprocessor, a microcontroller, a field programmable gate array, an application specific integrated circuit, or the like. The memory 160 may be a part of the electronic processor 150 or may be a separate component. The memory 160 may include, for example, a program storage area and a data storage area. The memory 160 stores executable instructions that when executed by the electronic processor 150, cause the power tool 100 to perform the functions described herein. For example, the electronic processor 150 controls the motor 170 and the current supply between a power source and the motor 170. The electronic processor 150 and the memory 160 together may form an electronic controller.

The motor 170 may be a brushless direct current motor. The inverter bridge 160 includes a plurality of field effect transistors (FETs) coupled between the battery pack 197 and the motor 170. The electronic processor 150 controls, for example, through a gate driver (not shown) that may be separate or incorporated into the electronic processor 150, a pulse width modulated cycle of the plurality of FETs to operate and control the speed of the motor 170. The electronic processor 150 may use closed-loop speed control, open-loop speed control, or a combination of the two to operate the motor. Particularly, in the present application, operating the motor 170 at a selected speed may include operating the motor 170 at a particular speed using closed-loop speed control, operating the motor 170 at a particular duty cycle using open-loop speed control, or the combination of the two. In closed-loop speed control, for example, the electronic processor 150 receives a desired speed (for example, via variable speed dial 140), drives the inverter bridge 160 at an initial pulse width modulated (PWM) duty cycle, detects speed of the motor 170 (for example, using Hall sensors), and adjusts the PWM duty cycle up or down to achieve the desired speed. In open-loop speed control, for example, the electronic processor 150 receives a desired speed (for example, via variable speed dial 140), accesses a lookup table stored in the memory 160 to obtain a PWM duty cycle mapped to the desired speed, and drives the inverter bridge 160 at the PWM duty cycle obtained from the memory 160.

The power tool 100 includes a transmission 175 (FIG. 1B) to convert the rotational motion of the motor 170 into a reciprocating motion to reciprocate the blade 120. That is, the rotation of the motor 170 is converted to strokes of the blade 120. The strokes per minute (SPM) of the blade 120 (i.e., the tool output speed) is set by controlling rotations per minute (RPM) of the blade 120 (i.e., motor speed). Accordingly, by controlling the motor speed (e.g., via open- or closed-loop speed control), the tool output speed is also controlled. The power tool 100 is activated by actuating the power switch 130. In the example illustrated, the power switch 130 is a slidable switch which can be moved between an ON position where the power tool 100 is turned ON to operate the motor 150 and an OFF position where the power supply to the motor 170 is terminated. In some embodiments, sliding the power switch 130 to the ON position may close the discharge switch 190 allowing current to flow from the power supply to the motor 170. Similarly, sliding the power switch 130 to the OFF position may open the discharge switch 190 terminating the current flow between the power supply and the motor 170. In other embodiments, the power switch 130 may be a different kind of switch, for example, a push-button, a trigger, and the like. In yet other embodiments, rather than directly controlling the discharge switch 190, the power switch 130 provides a signal to the electronic processor 150, which in turn controls the discharge switch 190 based on the signal received from the power switch 130.

The variable speed dial 140 is used to select an operating speed of the power tool 100. The variable speed dial 140 may include a plurality of settings each corresponding to a different operating speed. In one example, the variable speed dial 140 may include 6 settings corresponding to speeds between 800 strokes per minute (SPM) and 3500 SPM. The variable speed dial 140 may also be used to set the power tool 100 in an automatic controlled start mode. In the automatic controlled start mode, the motor 170 is operated at a low speed (for example, a speed corresponding to 1500 SPM) prior to detecting a load and the speed is ramped up to a maximum speed (for example, a speed corresponding to 3500 SPM) when a load is detected. A load, in this context, refers to a workpiece being engaged by the blade 120. The current sensor 195 measures a current flowing to the motor and provides an indication of the amount of current flow to the electronic processor 150.

Operating the power tool 100 at high speeds for long periods of time may generate heat in the power tool 100. The heat generated during these periods may damage electrical components of the power tool 100. When the jig saw 100 is loaded (that is, the power tool 100 is operating on a work piece), the power tool 100 may be automatically turned off due to battery discharge prior to generating excess heat. However, when the power tool 100 is unloaded and operated for extended periods of time (for example, 10 minutes, 15 minutes, or more) at high speeds, the power tool 100 may generate excess heat that may damage the components of the power tool 100. This situation may occur, for example, when a user has mounted the jig saw 100 for hands-free operation, turns the power tool 100 ON, and forgets to return to the power tool 100 to turn the power tool 100 OFF.

Returning to FIG. 1B, a perspective view of the power tool 100 of FIG. 1A with a portion of the housing 105 removed is shown. The housing 105, in the example illustrated, is a clamshell housing and half of the clamshell housing is removed in FIG. 1B. With the housing portion removed, internal components of the power tool 100 are visible, including the motor 170, the transmission 175, and a battery pack terminal block 198 for coupling to the battery pack 197.

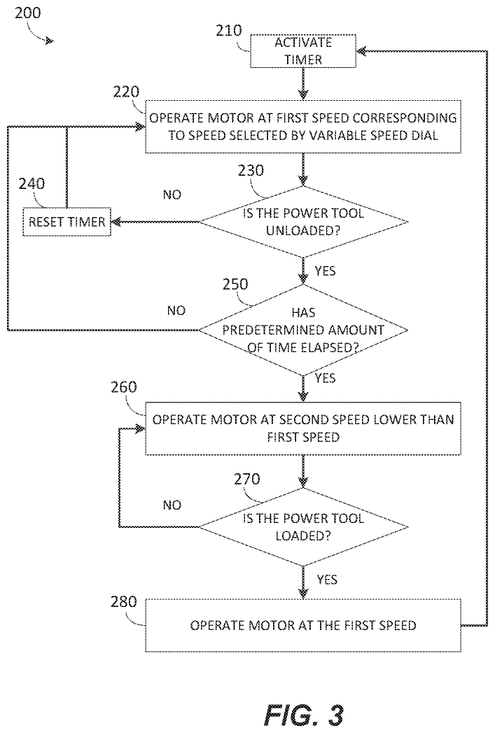

FIG. 3 illustrates a flowchart of a method 200 for heat management of the power tool 100. The method 200 includes activating, using the electronic processor 150 a timer (at block 210) and operating, using the electronic processor 150, the motor 170 at a first speed corresponding to a speed selected by the variable speed dial 140 (at block 220). A user may select the speed setting using the variable speed dial 140. The variable speed dial 140 sends a signal corresponding to the selected speed to the electronic processor 150. When the user actuates the power switch 130, the electronic processor 150 activates the timer and operates the motor at the selected speed (that is, the first speed). As discussed above, controlling the motor speed may include setting a PWM duty cycle for the FETs (open-loop speed control) and/or controlling rotations per minute of the motor 170 to be a particular value (closed-loop speed control) corresponding to the strokes per minute selected. The rotations per minute can be obtained by dividing the strokes per minute by the gear reduction ratio of the transmission mechanism. In some embodiments, rather than using a variable speed dial 140 to select a speed, the selected speed is a predetermined value stored in the memory 160 (for example, at the time of manufacture). In some embodiments, rather than using the variable speed dial 140 and the power switch 130, the power tool 100 includes a variable speed trigger, depressible by a user and providing signals to the electronic processor 150, used both to enable and disable the power tool 100 and also to input a selected speed for the motor 170.

The method 200 also includes determining, using the electronic processor 150, whether the power tool 100 is unloaded (at block 230). In one embodiment, the electronic processor 150 detects the load condition based on the amount of current flowing through the motor 170. For example, the electronic processor 150 determines that the power tool is unloaded when the instantaneous current is under a current threshold (for example, 20 Amperes) and determines that the power tool is loaded when the instantaneous current is above the threshold. In other embodiments, the electronic processor 150 determines that the tool 100 is loaded or unloaded based on changes in motor speed above a threshold, change in acceleration above a threshold, changes in average current above a threshold, a combination thereof, or by monitoring other tool parameters.

When the electronic processor 150 determines that the power tool 100 is loaded, the electronic processor 150 resets the timer (at block 240) and returns to block 220. By looping back through blocks 220, 230, and 240 while the power tool 100 continues to be loaded, the timer continues to be reset.

When the electronic processor 150 determines that the power tool 100 is unloaded (in block 230), the method 200 includes determining, using the electronic processor 150, whether a predetermined amount of time has elapsed (at block 250). The electronic processor 150 determines whether the predetermined amount of time has elapsed based on the timer. For example, in response to determining that a current value of the timer exceeds the predetermined amount of time by a comparison operation, the electronic processor 150 determines that the predetermined amount of time has elapsed. The predetermined amount of time may be selected to allow for continuous operation of the power tool at the selected speed without generating excess heat. In some embodiments, the predetermined amount of time is, for example, 1 minute, two minutes, 3 minutes, 5 minutes, 6 minutes, 10 minutes, 15 minutes, and the like. In some embodiments, the predetermined amount of time is between, for example, 1 minute and 5 minutes, 1 minute and 6 minutes, 1 minute and 10 minutes, 1 minute and 15 minutes, 2 minutes and 10 minutes, 3 minutes and 10 minutes, 5 minutes and 10 minutes, 5 minutes and 15 minutes, or any intervening range within these ranges, and the like. The predetermined amount of time is selected to prevent generation of excess heat rather than to place the tool at a lower speed when the tool is unloaded. That is, rather than performing load based speed control and selecting a time to prevent hysteresis, the predetermined amount of time is selected to prevent excess heat generation and is configured to be larger than a time for switching between a loaded speed and an unloaded speed. When the predetermined amount of time has not elapsed, the electronic processor 150 continues to operate the motor 170 at the first speed (returning to block 220).

When the predetermined amount of time has elapsed, the method 200 includes operating, using the electronic processor 150, the motor 170 at a second speed lower than the first speed (at block 260). The electronic processor 150 operates the motor 170 at a reduced speed (e.g., via open- or closed-loop speed control), for example, a speed corresponding to 1500 SPM, to prevent the power tool 100 from generating excess heat. The method 200 further includes determining, using the electronic processor 150, whether the power tool 100 is loaded (at block 270). As described above with respect to block 230, the electronic processor 150 may use a current based technique to determine whether the power tool 100 is loaded, or may use motor speed, acceleration, average current, or another technique to determine whether the power tool 100 is loaded. When the electronic processor 150 determines that the power tool 100 is unloaded, the electronic processor 150 continues to operate the power tool 100 at the second speed.

When the electronic processor 150 determines that the power tool 100 is loaded, the method 200 includes operating, using the electronic processor 150, the motor 170 at the first speed (at block 280) corresponding to the speed selected by the variable speed dial 140. In some embodiments, the method 200 repeats, returning to block 210 to restart the timer.

Accordingly, at least in some embodiments, by cycling between blocks 210, 220, 230, 240, and 250 and continuously resetting the timer upon the power tool 100 being loaded, the electronic processor 150 effectively operates the motor at the first speed unless the power tool 100 is unloaded for at least the predetermined amount of time. Particularly, the method 200 includes determining whether the power tool 100 is unloaded continuously for the duration of the predetermined period of time. The electronic processor 150 measures an instantaneous current flowing to the motor 170 or other motor parameter used to measure the load. The electronic processor 150 compares the instantaneous current to a predetermined current threshold and determines that the power tool 100 is unloaded when the instantaneous current is below the threshold. The electronic processor 150 determines that the power tool 100 is loaded when the instantaneous current is at or above the threshold. The electronic processor 150 repeats the above steps, that is, measuring instantaneous current, comparing the measured current to the predetermined current threshold and determining the load state of the power tool 100 at discrete time intervals. For example, the electronic processor 150 repeats the above steps every several milliseconds, e.g., every 50 or 100 ms. Thus, at least in some embodiments, the electronic processor 150 determines that the power tool 100 is unloaded continuously for the duration of the predetermined period of time when, at each discrete interval during the predetermined period of time, the measured instantaneous current is below the threshold.

Then, at least in some embodiments, by cycling between blocks 260 and 270, the electronic processor 150 effectively operates the motor at the second speed until the power tool 100 becomes loaded, at which point the speed is raised back to the first speed (in block 280).

One advantage of the above method is to prevent generation of excess heat and to prevent damage to the electronic components of the power tool 100.

Thus, embodiments described herein provide, among other things, a system and method for heat management using speed control for a power tool.

1. A power tool comprising:
a housing;
a motor within the housing;
a variable speed dial moveable between a plurality of positions to select an operating speed of the motor; and
an electronic controller coupled to the motor and the variable speed dial and configured to:
operate the motor at a first speed corresponding to a speed selected by the variable speed dial,
determine whether the power tool has been unloaded for a predetermined amount of time during which the motor has been operated at the first speed,
in response to determining that the motor has been unloaded for the predetermined amount of time, operate the motor at a second speed lower than the first speed,
determine whether the power tool is loaded while operating the motor at the second speed, and
in response to determining that the motor is loaded, operate the motor at the first speed.

2. The power tool of claim 1, wherein the predetermined amount of time is at least 1 minute.

3. The power tool of claim 1, wherein the electronic processor is further configured to:
determine whether the power tool has been unloaded continuously for the duration of the predetermined amount of time, and
determine that the motor has been unloaded for the predetermined amount of time in response to determining that the power tool has been unloaded continuously for the duration of the predetermined amount of time.

4. The power tool of claim 3, wherein the electronic processor is further configured to:
determine that the power tool is unloaded;
start a timer in response to determining that the power tool is unloaded, wherein the timer expires when the timer counts to the predetermined amount of time;
determine whether the power tool is unloaded for the duration of the timer from the start until the timer expires; and
determine that the power tool has been unloaded continuously for the duration of the predetermined amount of time when the power tool is unloaded for the duration of the timer from the start until the timer expires.

5. The power tool of claim 4, wherein the electronic processor is further configured to:
determine whether the power tool is loaded after starting the timer but before the timer expires; and
reset the timer in response to determining that the power tool is loaded after starting the timer but before the timer expires.

6. The power tool of claim 5, further comprising a current sensor for measuring a current flowing to the motor, wherein the electronic processor is further configured to:
measure, using the current sensor, an instantaneous current flowing to the motor;
compare the instantaneous current to predetermined current threshold;
determine that the power tool is unloaded when the current is below the predetermined current threshold; and
determine that the power tool is loaded when the current is at or above the predetermined current threshold.

7. The power tool of claim 6, wherein, to determine whether the power tool is unloaded for the duration of the timer from the start until the timer expires, the electronic processor is configured to determine whether the power tool is unloaded at discrete time intervals from the start of the timer until the timer expires.

8. The power tool of claim 1, wherein operating the motor at the first speed and the second speed further includes operating the motor using open loop speed control or closed loop speed control.

9. A method for heat management of a power tool comprising:
operating, using an electronic processor of the power tool, the motor at a first speed corresponding to a speed selected by a variable speed dial of the power tool;
determining, using the electronic processor, that the power tool has been unloaded for a predetermined amount of time during which the motor has been operated at the first speed;
in response to determining that the motor has been unloaded for the predetermined amount of time, operating, using the electronic processor, the motor at a second speed lower than the first speed,
determining, using the electronic processor, that the power tool is loaded while operating the motor at the second speed, and
in response to determining that the motor is loaded, operating, using the electronic processor, the motor at the first speed.

10. The method of claim 9, wherein the predetermined amount of time is at least 1 minute.

11. The method of claim 9, further comprising:
determining whether the power tool has been unloaded continuously for the duration of the predetermined amount of time, and
determining that the motor has been unloaded for the predetermined amount of time in response to determining that the power tool has been unloaded continuously for the duration of the predetermined amount of time.

12. The method of claim 11, further comprising:
determining that the power tool is unloaded;
starting a timer in response to determining that the power tool is unloaded, wherein the timer expires when the timer counts to the predetermined amount of time;
determining whether the power tool is unloaded for the duration of the timer from the start until the timer expires; and
determining that the power tool has been unloaded continuously for the duration of the predetermined amount of time when the power tool is unloaded for the duration of the timer from the start until the timer expires.

13. The method of claim 12, further comprising:
determining whether the power tool is loaded after starting the timer but before the timer expires; and
resetting the timer in response to determining that the power tool is loaded after starting the timer but before the timer expires.

14. The power tool of claim 13, further comprising:
measuring, using a current sensor, an instantaneous current flowing to the motor;
comparing the instantaneous current to predetermined current threshold;
determining that the power tool is unloaded when the current is below the predetermined current threshold; and
determining that the power tool is loaded when the current is at or above the predetermined current threshold.

15. The power tool of claim 14, wherein determining whether the power tool is unloaded for the duration of the timer from the start until the timer expires includes determining whether the power tool is unloaded at discrete time intervals from the start of the timer until the timer expires.

16. A power tool comprising:
a housing;
a motor within the housing; and
an electronic controller coupled to the motor and configured to:
operate the motor at a first speed,
determine whether the power tool has been unloaded for a predetermined amount of time during which the motor has been operated at the first speed,
in response to determining that the motor has been unloaded for the predetermined amount of time, operate the motor at a second speed lower than the first speed,
determine whether the power tool is loaded while operating the motor at the second speed, and
in response to determining that the motor is loaded, operate the motor at the first speed.

17. The power tool of claim 16, wherein the predetermined amount of time is at least 1 minute.

18. The power tool of claim 16, wherein the electronic processor is further configured to:
determine whether the power tool has been unloaded continuously for the duration of the predetermined amount of time, and
determine that the motor has been unloaded for the predetermined amount of time in response to determining that the power tool has been unloaded continuously for the duration of the predetermined amount of time.

19. The power tool of claim 18, wherein the electronic processor is further configured to:
determine that the power tool is unloaded;
start a timer in response to determining that the power tool is unloaded, wherein the timer expires when the timer counts to the predetermined amount of time;
determine whether the power tool is unloaded for the duration of the timer from the start until the timer expires; and
determine that the power tool has been unloaded continuously for the duration of the predetermined amount of time when the power tool is unloaded for the duration of the timer from the start until the timer expires.

20. The power tool of claim 19, wherein the electronic processor is further configured to:
determine whether the power tool is loaded after starting the timer but before the timer expires; and
reset the timer in response to determining that the power tool is loaded after starting the timer but before the timer expires.
